(19) United States
(12) Patent Application Publication
(10) Pub. No.: US 2025/0038128 A1
(43) Pub. Date: Jan. 30, 2025

(54) STACKED SEMICONDUCTOR DEVICE AND METHOD OF MANUFACTURING THE SAME

(71) Applicant: SK hynix Inc., Gyeonggi-do (KR)

(72) Inventor: Hee Sun LEE, Gyeonggi-do (KR)

(21) Appl. No.: 18/414,477

(22) Filed: Jan. 17, 2024

(30) Foreign Application Priority Data
Jul. 24, 2023 (KR) 10-2023-0096102

(51) Int. Cl. H01L 23/00

(52) U.S. Cl. CPC H01L 23/562; H01L 24/32; H01L 2224/32145

(57) ABSTRACT

A stacked semiconductor device may include a first wafer and at least one first insulation support pattern. The first wafer may include a first surface having at least one insulation layer and a second surface opposite to the first surface. The first insulation support pattern may be extended from the first surface of the first wafer into the insulation layer. The first insulation support pattern may be formed in a region of the first surface where an integrated circuit may not be formed.

### CROSS-REFERENCES TO RELATED APPLICATION

The present application claims priority under 35 U.S.C. § 119 (a) to Korean application number 10-2023-0096102, filed on Jul. 24, 2023, in the Korean Intellectual Property Office, which is incorporated herein by reference in its entirety.

### BACKGROUND

### 1. Technical Field

Various embodiments generally relate to a stacked semiconductor device and, more specifically, to a stacked semiconductor device with improved supporting strength at an edge portion in a wafer bonding, and to a method of manufacturing the stacked semiconductor device.

### 2. Related Art

Wafer bonding is a well-known technology for three-dimensionally stacking semiconductor devices with an integrated circuit (IC).

Wafer bonding electrically connects at least two stacked semiconductor devices with each other.

According to typical wafer bonding, a gap or a void may be generated between edge portions of the stacked semiconductor devices due to a thin thickness of a wafer bevel region.

The gap or the void may cause a delamination, a crack, etc., of a bonding portion of the stacked semiconductor devices in a following wafer thinning process. Hence, developing improved wafer bonding that reduces or eliminates gap formation would be highly desirable.

### SUMMARY

According to example embodiments, there is provided a stacked semiconductor device which includes a first wafer, at least one first insulation layer and at least one first insulation support pattern. The first insulation layer is formed over an upper surface of the first wafer. The first insulation support pattern is extended from an upper surface of the first insulation layer to the first wafer.

According to example embodiments, there is provided a stacked semiconductor device. The stacked semiconductor device may include a first wafer, at least one first insulation support pattern, a second wafer and at least one second insulation support pattern. The first wafer may include a first surface having at least one insulation layer and a second surface opposite to the first surface. The first insulation support pattern may be extended from the first surface of the first wafer into the insulation layer. The second wafer may include a third surface having at least one insulation layer. The third surface may be bonded to the first surface of the first wafer. The second insulation support pattern may be extended from the third surface into the insulation layer of the second wafer. The first insulation support pattern and the second insulation support pattern may be bonded to each other at a bonded surface between the first surface and the third surface.

According to example embodiments, there is provided a method of manufacturing a stacked semiconductor device. In the method of manufacturing the stacked semiconductor device, the insulation layer is formed on an upper surface of the first wafer. At least one insulation layer and a portion of the first wafer is etched to form at least one recess. An edge gap-filling layer is formed over the insulation layer to fill the recess. The edge gap-filling layer is planarized to expose the insulation layer of the first wafer, to form an edge-filling layer and at least one insulation support pattern formed in the edge-filling layer.

According to example embodiments, when the semiconductor devices are stacked by the wafer bonding, the insulation support patterns of the stacked semiconductor devices may be bonded to each other to provide supporting strength. Thus, a delamination, a crack, a peeling, etc., at the edge portion of the stacked semiconductor device may be prevented in a following process such as a wafer thinning process using a chemical mechanical polishing (CMP) process.

### BRIEF DESCRIPTION OF THE DRAWINGS

The above and other aspects, features and advantages of the subject matter of the present invention disclosure will be more clearly understood from the following detailed description taken in conjunction with the accompanying drawings, in which:

FIG. 1 is a plan schematic illustrating a semiconductor device in accordance with example embodiments of the present invention disclosure;

FIG. 2A is an enlarged schematic of a portion “A” in FIG. 1;

FIG. 2B is a cross-sectional schematic taken along a line X-X′ in FIG. 2A;

FIGS. 3A and 3B are cross-sectional schematics illustrating a bevel portion of a stacked semiconductor device in accordance with example embodiments of the present invention disclosure;

FIGS. 4A and 4B are cross-sectional schematics illustrating a stacked semiconductor device with an edge gap-filling layer in accordance with example embodiments of the present invention disclosure;

FIGS. 5A to 5D are cross-sectional schematics illustrating stacked semiconductor device with various insulation support patterns in accordance with example embodiments of the present invention disclosure;

FIGS. 6A and 6B are plan schematics illustrating a die with various insulation support patterns in accordance with example embodiments of the present invention disclosure;

FIG. 7 is a flow chart illustrating a method of manufacturing a stacked semiconductor device in accordance with example embodiments of the present invention disclosure;

FIG. 8 is plan schematic illustrating an exposure range of an exposure apparatus for forming an insulation support pattern in accordance with example embodiments of the present invention disclosure;

FIGS. 9A to 9D are a schematic illustrating a method of recess for the insulation support pattern in accordance with example embodiments of the present invention disclosure;

FIGS. 10A to 10F are a schematic illustrating a method of forming a gap-filling insulation layer formed on the wafer in accordance with example embodiments of the present invention disclosure; and

FIGS. 11A to 11D are a schematic illustrating method of manufacturing a stacked semiconductor device in accordance with example embodiments.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the scope of the present invention.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and scope of the present invention.

The term “a” or “an” element refers to one or more of that element. As such, the terms “a” or “an,” or “one or more” and “at least one” may be used interchangeably.

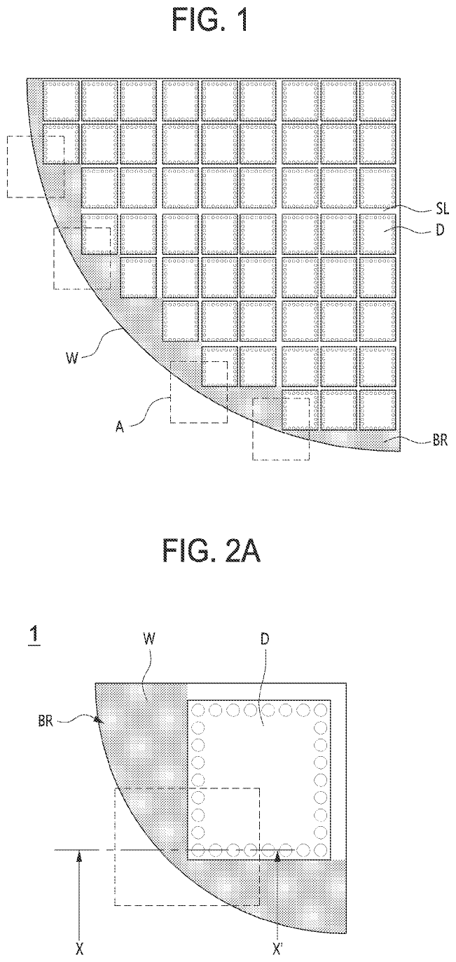

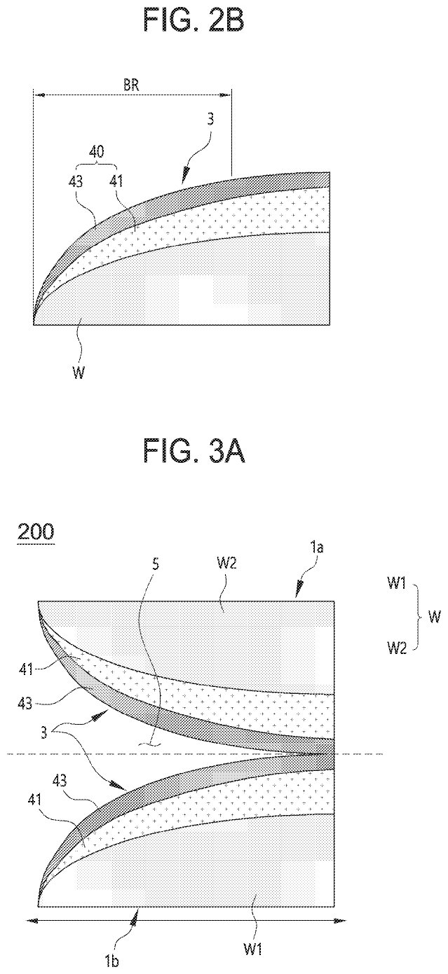

FIG. 1 is a plan schematic illustrating a part of a wafer in a stacked semiconductor device in accordance with example embodiments, FIG. 2A is an enlarged schematic of a portion “A” in FIG. 1 and FIG. 2B is a cross-sectional schematic taken along a line X-X′ in FIG. 2A. Referring to FIGS. 1, 2A and 2B, a semiconductor device 1 may include a wafer W. The wafer W may include a plurality of dies D and at least one insulation layer 40. For example, the plurality of dies D may be defined by a scribe lane SL. More specifically, a plurality of horizontal and vertical lanes may divide the wafer W in a plurality of rectangular (e.g., square) dies D. The insulation layer 40 may be formed over or on an upper surface of the wafer W including the plurality of dies D. The insulation layer 40 may be in direct contact with the upper surface of the wafer W. In the illustrated example embodiment of FIG. 1, the insulation layer 40 includes a first insulation layer 41 and a second insulation layer 43. It is noted, however, that in other embodiments the insulation layer 40 may include one or more insulation layers without departing from the scope of the present invention. The first insulation layer 41 may include a silicon oxide layer such as tetraethoxysilane (TEOS). For example, the second insulation layer 43 may include silicon carbon nitride (SCN).

Further, the wafer W may include at least one conductive pattern in or on the insulation layer 40.

The wafer W may include a bevel region BR corresponding to an edge area of the wafer W. The bevel region BR may have an edge profile having gradually decreased thicknesses along a circumferential direction of the wafer W in a CMP process, a deposition process, etc. In other word, layers formed over the bevel region BR may have a relatively thinner thickness than those formed on a center region of the wafer W. Thus, an edge slant surface 3 may be formed on the bevel region BR. For example, a width d1 of the bevel region BR may be within about 2 mm from an edge toward the center region.

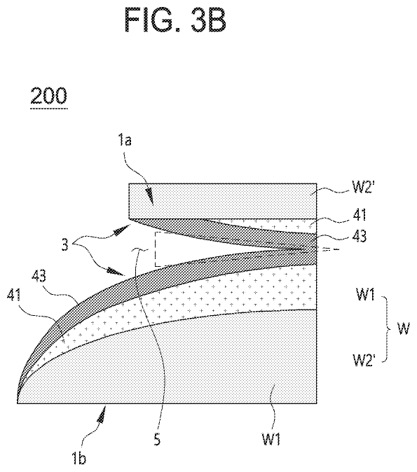

FIGS. 3A and 3B are cross-sectional schematics illustrating a bevel portion of a stacked semiconductor device in accordance with example embodiments.

Referring to FIGS. 3A and 3B, a stacked semiconductor structure 200 may include a first semiconductor device 1a and a second semiconductor device 1b. Each of the first and second semiconductor devices 1a and 1b may include the bevel region BR, as above described. Each of the bevel regions BR may include the edge slant surface 3.

Referring to FIG. 3A, the first and second semiconductor devices 1a and 1b may not be completely bonded to each other, due to the edge slant surfaces 3. Thus, a gap (or a void) 5 between the first and second semiconductor devices 1a and 1b in the stacked semiconductor structure 200 may be generated along the bevel region BR of the stacked semiconductor structure 200.

Referring to FIG. 3B, the gap 5 may cause a delamination, a crack, a peeling, etc., in a following process such as a CMP process. Reasons of the delamination, the crack, the peeling, etc., may be a pressure, a heat, etc., used in the following process. A reference numeral W2′ indicates a state in which an edge portion (substrate and insulation layer) of the wafer W2 has been partially removed.

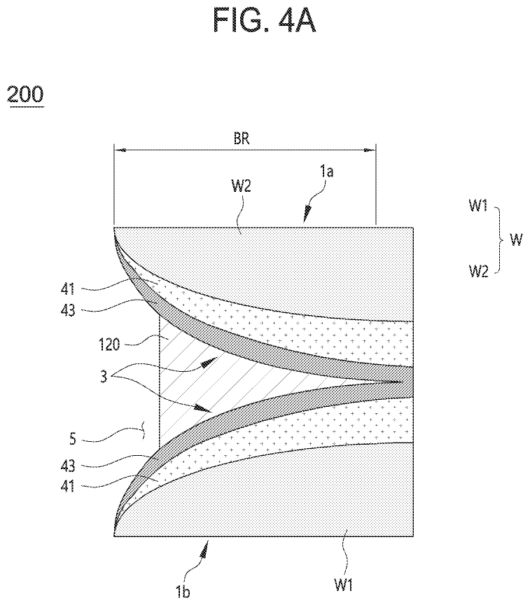

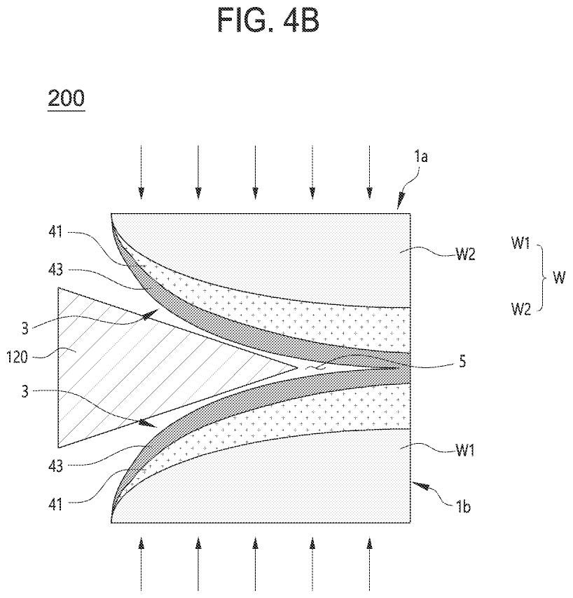

FIGS. 4A and 4B are cross-sectional schematics illustrating a stacked semiconductor device with an edge gap-filling layer in accordance with example embodiments of the present invention.

Referring to FIG. 4A, the gap 5 may be filled with a gap-filling material to form an edge gap-filling layer 120 for sealing the gap 5 at least partially and providing support to the bevel edge regions BR of the first and second wafers W1 and W2. The edge gap-filling layer 120 strengthens the bevel region of the first and second stacked wafers W1 and W2 and may thus prevent damage or chipping away of the bevel region (in the form of delamination, cracking, peeling, etc.,) of the stacked semiconductor structure 200 caused by the gap 5.

For example, the edge gap-filling layer 120 may be inserted to the gap 5 between the bevel regions BR of the first and second semiconductor devices 1a and 1b.

In example embodiments, the edge gap-filling layer 120 may include at least one of an insulation layer, a dielectric material, and a polymer which are formed at low temperature of less than 250 degree Celsius (° C.).

For example, the edge gap-filling layer 120 may include at least one polysilazane (PSZ) layer, an oxide layer, a nitride layer, and an oxynitride layer. In example embodiments, the edge gap-filling layer 120 may be formed by various processes such as a spin on dielectric (SOD) process, CVD (chemical vapor deposition), PVD (physical vapor deposition) and ALD (atomic layer deposition), and the like.

However, the edge gap-filling layer 120 may slip from the wafers W1 and W2 or at least one of the crack, the delamination and the peeling is generated in the edge gap-filling layer 120 when the wafer W1 or W2 is polished to thin the wafer W1 or W2, due to the pressure and the heat during the process for the thinning the wafer W1 or W2, as shown in FIG. 4B.

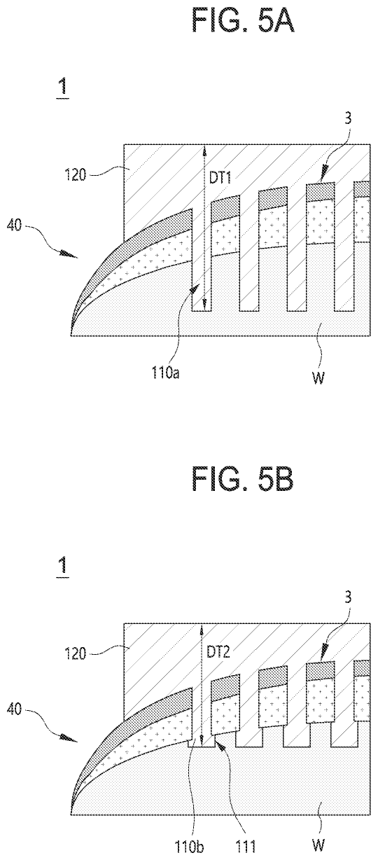

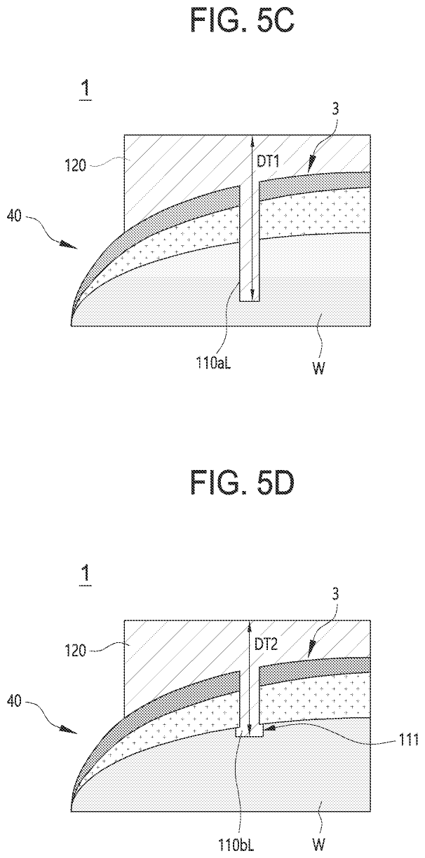

FIGS. 5A to 5D are cross-sectional schematics illustrating a bevel region of a semiconductor device with various insulation support patterns in accordance with example embodiments. Referring to FIGS. 5A to 5D, the semiconductor device 1 may include a wafer W, an insulation layer 40, and an edge gap-filing layer 120.

The insulation layer 40 may be formed over an upper surface of the wafer W. The insulation layer 40 may include a plurality of insulation layers which are stacked. The insulation layer 40 and the wafer W of the bevel region may be etched to form at least one recess. A depth of the recess may be controlled by the amount of etching the wafer W. The edge gap-filing layer 120 may be formed over the insulation layer 40 where the recess is formed. The recess is buried by the edge gap-filing layer 120, to form at least one insulation support pattern 110a or 110b.

Alternatively, the edge gap-filling layer 120 may be formed by bonding the two stacked semiconductor devices 1 to each other, injecting the gap-filling material into a gap between the bevel regions of the two semiconductor devices 1.

For example, referring to FIG. 5A, the insulation support patterns 110a may be formed to have a first depth DT1 from an upper surface of the edge gap-filling layer 120 in the bevel region BR. For example, the insulation support patterns 110a may be formed at regular intervals in the bevel region BR. Here, depths of the recesses in which each of the insulation support patterns 110a is formed may gradually become shallower toward the edge of the wafer W due to the edge slant surfaces 3.

Referring to FIG. 5B, the insulation support patterns 110b may be formed to have a second depth DT2 from the upper surface of the edge gap-filling layer 120 in the bevel region BR. The second depth D2T may be smaller than the first depth DT1. Here, depths of the recesses in which each of the insulation support patterns 110b is formed may gradually become shallower toward the edge of the wafer W due to the edge slant surfaces 3. Further, a width of the recess in the wafer W may be different from a width of the recess in the insulation layer 40. For example, the width of the recess in the wafer W may be wider than the width of the recess in the insulation layer 40. Thus, the insulation support patterns 110b may have a protruding groove 111. The protruding groove 111 may act as a bump, and, thus, the insulation support patterns 110b may be more stably fixed within the insulation layer 40 and the wafer W.

Referring to FIGS. 5C and 5D, a first insulation support patterns 110aL and 110bL may be formed to in a line shape (in a planar structure) along the bevel region BR. For example, a cross-sectional structure of the first insulation support patterns 110al may be same as that of the first insulation support pattern 110a (FIG. 5A). A cross-sectional structure of the first insulation support pattern 110bL may be same as that of the first insulation support pattern 110b (FIG. 5B).

The insulation support patterns 110a, 110b, 110aL and 110bL may be formed in the bevel region of the wafer W, but may be not limited thereto.

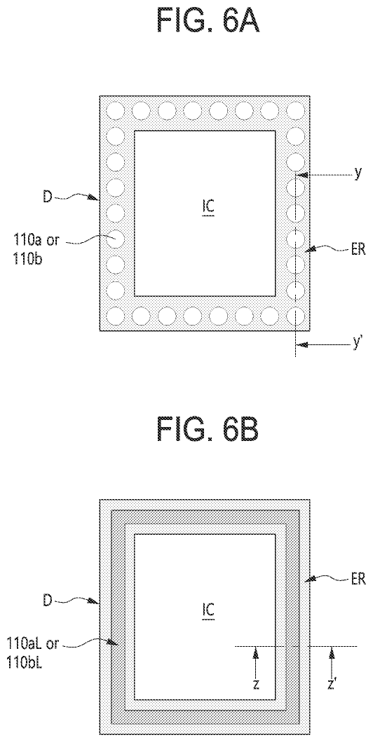

FIGS. 6A and 6B are plan schematics illustrating a die with various insulation support patterns in accordance with example embodiments.

Referring to FIGS. 1, 6A and 6B, the wafer W may include the plurality of dies D. Each of the dies may include an integrated circuit (IC) region “IC” and an edge area ER. The edge area ER may surround the IC region “IC”. For example, the edge area ER may include a scribe lane or an area in which pads are arranged.

For example, the insulation support patterns 110a and 110b of FIGS. 5A and 5B may be formed in the edge area ER of the die D. For example, at least one of the first and second insulation support patterns 110a and 110b may be formed in the edge area ER of the die D in a pattern shape, as shown in FIG. 6A. Further, the insulation support patterns 110a and 110b may be formed in the edge area ER of the die D in a line shape, as shown in FIG. 6B.

Since the insulation support patterns 110a and 110b are formed in the edge area ER of the die D, an adhesion between the dies to be bonded is improved.

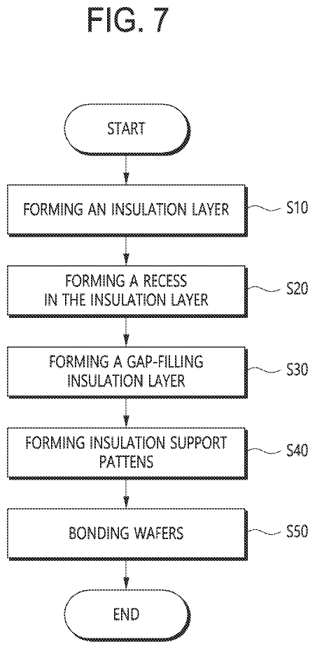

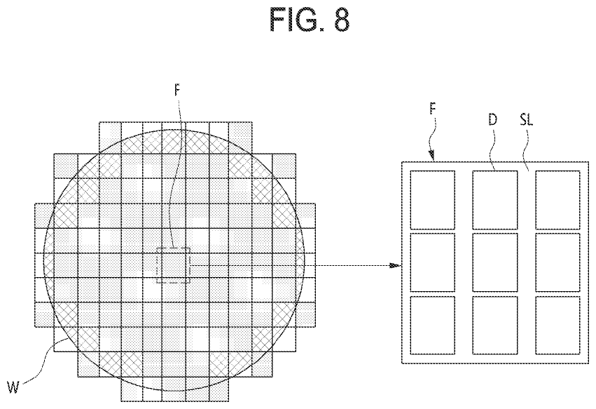

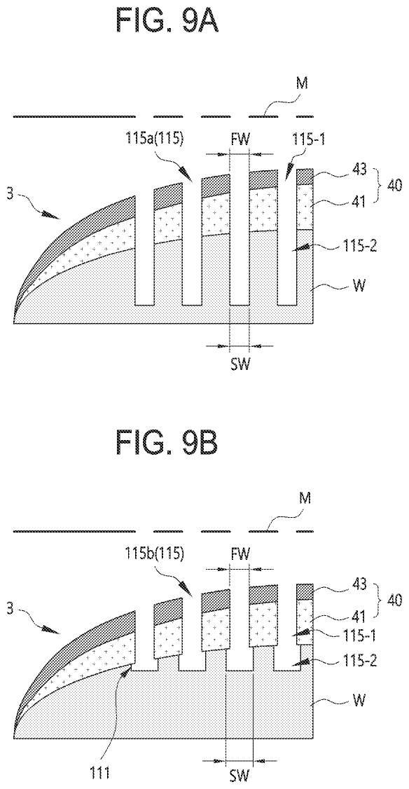

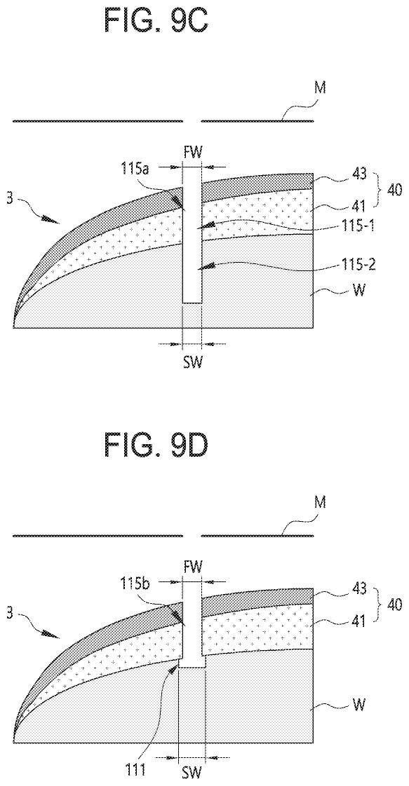

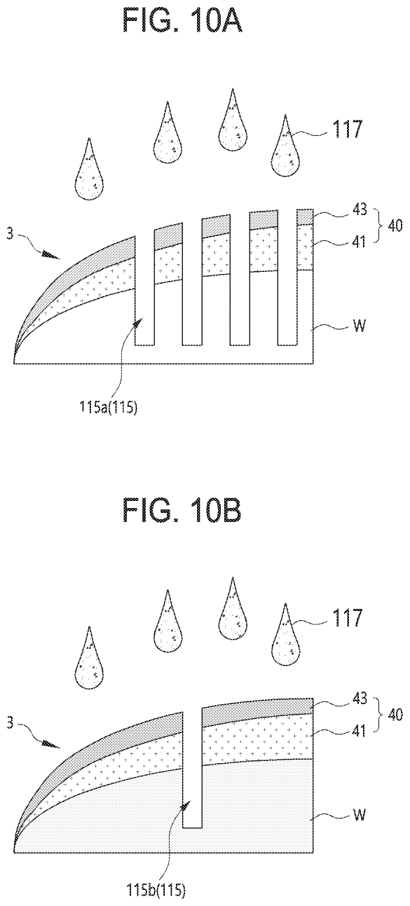

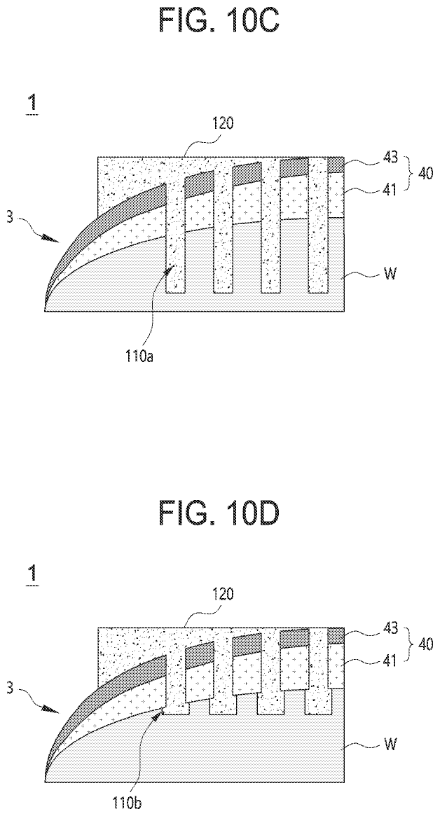

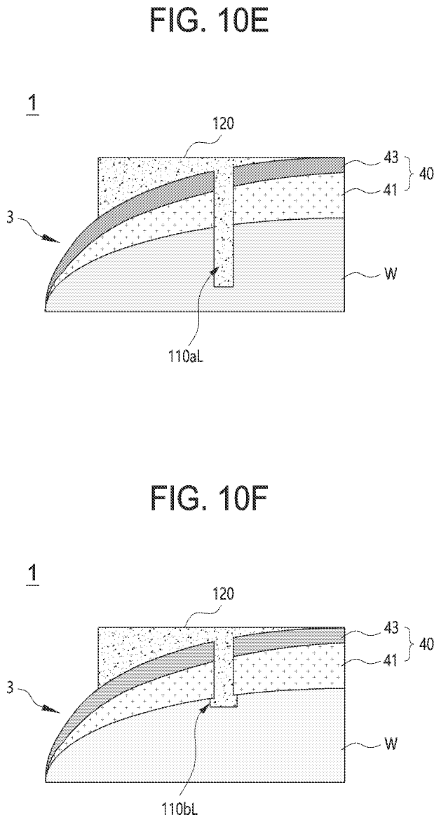

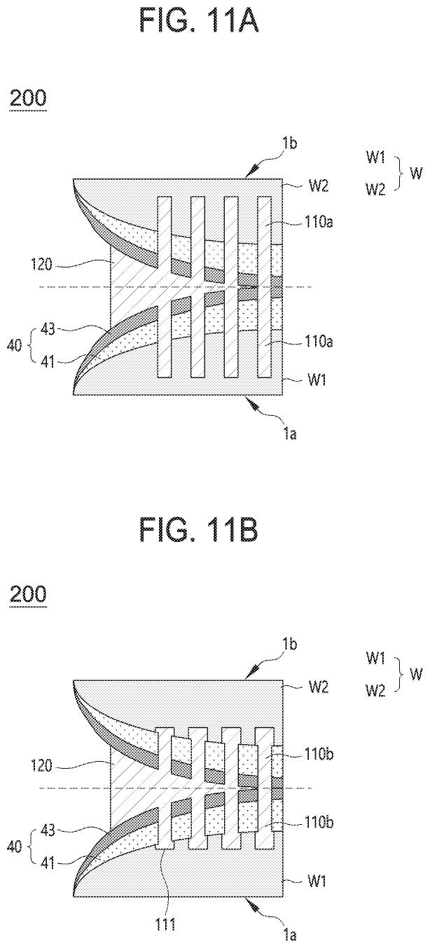

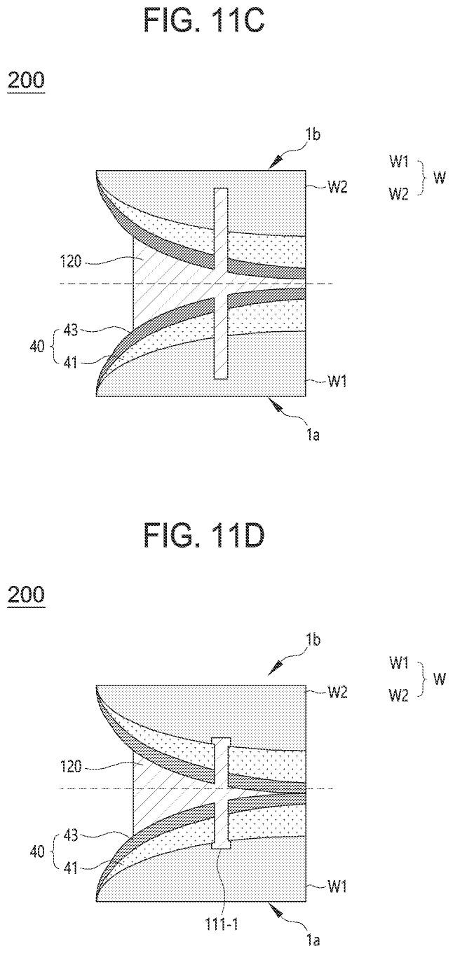

FIG. 7 is a flow chart illustrating a method of manufacturing a stacked semiconductor device in accordance with example embodiments. FIG. 8 is plan schematics illustrating an exposure range of an exposure apparatus for forming an insulation support pattern in accordance with example embodiments. FIGS. 9A to 9D are a schematic illustrating a method of recess for the insulation support pattern in accordance with example embodiments. FIGS. 10A to 10B are a schematic illustrating a method of forming a gap-filling insulation layer formed on the wafer in accordance with example embodiments. FIGS. 11A to 11D are a schematic illustrating method of manufacturing a stacked semiconductor device in accordance with example embodiments. For reference, FIGS. 9A and 9B are cross-sectional schematics taken along a line Y-Y′ in FIG. 6A. FIGS. 9C and 9D are cross-sectional schematics taken along a line Z-Z′ in FIG. 6B.

Referring to FIGS. 1 to 11D, a method of manufacturing a stacked semiconductor device may include a process S10 for forming an insulation layer, a process S20 for forming a recess in the insulation layer, a process S30 for forming an edge gap-filling layer and a process S40 for planarizing the edge gap-filling layer. The method may further include a process S50 for bonding wafers to each other.

In process S10, at least one insulation layer 40 may be formed over an upper surface of the wafer W. For example, the wafer W may include a plurality of dies D formed on an upper surface thereof. The plurality of dies D is divided by a scribe lane SL. Further, the IC region “IC” may be formed on the upper surface of the wafer W, that is, upper surfaces of the plurality of dies D in the wafer W. That is, the insulation layer 40 may be formed over the upper surfaces of the plurality of dies D, respectively.

In process S20, at least one recess may be formed in the insulation layer 40 and the wafer W using an insulation support pattern mask M. In example embodiments, the recess may be formed in at least one of the insulation layer 40 on the bevel region BR and the insulation layer 40 on the edge area ER of the die D.

For example, the recess 115 may include a first recess 115-1 formed in the insulation layer 40 and a second recess 115-2 formed in the wafer W. The first recess 115-1 and the second recess 115-2 may be connected to each other. The first recess 115-1 may include a first width FW and the second recess 115-2 may include a second width SW. For example, the second width SW may be same with the first width FW, as shown in FIGS. 9A and 9C. Alternately, the second width SW may be wider than the first width FD, as shown in FIGS. 9B and 9D.

For example, the insulation support pattern mask M may be applied to the wafer W by a field unit F. Here, the field is an area where a single exposure process of a photolithography process is performed. Thus, the field may include some of the dies.

The insulation support pattern mask M may be selectively arranged the fields including the bevel region BR, which may be indicated by “A” in FIG. 1, among the first and second wafers W1 and W2. Thus, the recess 115, 115a and 115b may be formed at the bevel region BR of the upper surface of the wafer W.

For example, the wafer W and the insulation layer 40 may be individually etched using two insulation support pattern masks with different line widths, to form a protruding groove 111. Alternately, when the insulation layer 40 and the wafer W are etched using a single insulation support pattern mask M, the wafer W may be over etched, to form the protruding groove 111. For example, the over etching of the wafer W may be used by isotropic and anisotropic etching processes.

In process S30, a gap-filling insulation layer may be formed over the wafer W to fill the recess 115.

In example embodiments, in process S30, the gap-filling material may be formed over the wafer W with the recess 115, 115a and 115b.

For example, the gap-filling material 117 may be coated over the wafer W by a spin coating method, PVD (physical vapor deposition), etc., as shown in FIGS. 10A and 10B. For example, the gap-filling material 117 may include a liquid source, a glass material, SOD (spin on dielectric), a polysilazane and nitride material, etc.

The coated gap-filling material 117 may be annealed (or cured) to form an edge gap-filling layer 120 under 200° C. to 300° C., but not limited thereto, as shown in FIGS. 10C to 10F. Since the gap-filling material 117 is hardened through the annealing process to form the edge gap-filling layer 120 with a certain thickness.

In process S40, the edge gap-filling layer 120 is planarized by a CMP process to expose the insulation layer 40 at the wafer W, to form insulation support patterns 110, 110a, 110b, 110aL, 110bL in the recess 115. As above mentioned, the bevel region BR of the wafer W include the edge slant surface 3. Accordingly, there is a height difference between an upper surface of the insulation layer 40 at the bevel region BR and the upper surface of the insulation layer 40 at the center of the wafer W. When the planarization process of the gap-filing layer 120 is performed, the gap-filing layer 120 remains on an edge portion of the wafer W, that is, the bevel region BR. Hereinafter, the reference numeral 120 will be referred to as an edge gap-filing layer.

In process S50, the insulation layers 40 of the first and second wafers W1 and W2 may be bonded to each other by a compression, as shown in FIGS. 11A to 11D. In example embodiments, pads of the first and second wafers W1 and W2 may be bonded to each other by heating. Further, the insulation support patterns 110a, 110b, 110aL, 110bL may be bonded to each other by heating. The pads are formed in the insulation layers 40 of the first and second wafers W1 and W2, respectively.

In process S50, the edge gap-filling layer 120 may be formed between the bevel portions (or edge portions) of the first and second wafers W1 and W2.

In example embodiments, the wafer bonding may include a wafer direct bonding, an atomic diffusion bonding (ADB), a surface activated bonding (SAB), a thermal compression bonding such as Cu—Cu thermo-compression bonding, a normal temperature and pressure bonding such as Cu-direct bonding-LETI approach, a solid liquid inter-diffusion bonding (SLID), a hybrid wafer bonding, a flip chip bonding, etc.

The above described embodiments of the present invention are intended to illustrate and not to limit the present invention. Various alternatives and equivalents are possible. The invention is not limited by the embodiments described herein. Nor is the invention limited to any specific type of semiconductor device. A person having ordinary skill in the art would recognize that various additions, subtractions, or modifications to the disclosed embodiments are feasible, and should fall within the scope of the present disclosure.

1. A stacked semiconductor device comprising:
a first wafer;
at least one first insulation layer formed over an upper surface of the first wafer; and
at least one first insulation support pattern extended from an upper surface of the first insulation layer to the first wafer.

2. The stacked semiconductor device of claim 1, wherein the first wafer comprises a plurality of dies and a bevel region surrounding the plurality of dies,
wherein the plurality of dies are divided by a scribe lane; and
wherein the first insulation support pattern is arranged at least one of the bevel region and the scribe lane.

3. The stacked semiconductor device of claim 1, further comprising:
a second wafer;
at least one second insulation layer formed over an upper surface of the second wafer, the second insulation layer being bonded to the first insulation layer; and
at least one second insulation support pattern extended from the upper surface of the first insulation layer to the second wafer,
wherein the second insulation support pattern is arranged at a position facing to the first insulation support.

4. The stacked semiconductor device of claim 3, wherein an edge gap-filling layer is formed between bevel regions of the first and second wafers.

5. The stacked semiconductor device of claim 3, wherein the edge gap-filling layer comprises a material substantially the same as materials of the first and second insulation support patterns.

6. The stacked semiconductor device of claim 3, wherein the first and second insulation support patterns have substantially the same width.

7. The stacked semiconductor device of claim 3, wherein a width of the first and second insulation support patterns in the first and second insulation layers is narrower than a width of the first and second insulation support patterns in the first and second wafers.

8. The stacked semiconductor device of claim 3, wherein at least one of the first and second insulation support patterns include a line shape or a pattern shape in a plan schematic.

9. A stacked semiconductor device comprising:
a first wafer including a first surface with at least one first insulation layer and a second surface opposite to the first surface;
at least one first insulation support pattern extended from the first surface into the first insulation layer;
a second wafer including a third surface with at least one second insulation layer bonded to the first surface of the first wafer; and
at least one second insulation support pattern extended from the third surface into the second insulation layer,
wherein the first and second insulation support patterns are bonded to each other at an bonded surface between the first surface and the third surface.

10. The stacked semiconductor device of claim 9, wherein the first and second wafers comprise a plurality of dies divided by a scribe lane on the first and third surfaces, respectively, and the first and second insulation support patterns are arranged in at least one of the scribe lane and an edge portion of each of the dies.

11. The stacked semiconductor device of claim 9, wherein the first insulation support pattern and the second insulation support pattern are positioned in bevel regions corresponding to edge portions of the first and second wafers.

12. The stacked semiconductor device of claim 10, further comprising: an edge gap-filling layer formed between bevel regions of the first and second wafers,
wherein the first and second insulation support patterns are arranged at the edge gap-filling layer.

13. The stacked semiconductor device of claim 12, wherein the edge gap-filling layer comprises a material substantially the same as materials of the first and second insulation support patterns.

14. The stacked semiconductor device of claim 9, wherein the first and second insulation support patterns have substantially the same width.

15. The stacked semiconductor device of claim 9, wherein a width of the first and second insulation support patterns in the insulation layer is smaller than a width of the first and second insulation support patterns in the first and second wafers.

16-20. (canceled)

21. A stacked semiconductor device comprising:
a first wafer;
a second wafer;
at least one first insulation layer formed over an upper surface of the first wafer, the first insulation layer including at least one first recess penetrating the first insulation layer and a part of the first wafer;
at least one first insulation support pattern formed in the first recess extended from an upper surface of the first insulation layer to the first wafer;
at least one second insulation layer formed over an upper surface of the second wafer, the second insulation layer being bonded to the first insulation layer; and
at least one second insulation support pattern extended from the upper surface of the first insulation layer to the second wafer,
wherein the second insulation support pattern is arranged at a position facing to the first insulation support.

22. The stacked semiconductor device of claim 21, wherein the second insulation layer includes
at least one second recess penetrating the second insulation layer and a part of the second wafer,
wherein the at least one second insulation support pattern is formed in the second recess.
